(19) United States
(12) Patent Application Publication
(10) Pub. No.: US 2015/0279873 A1
(43) Pub. Date: Oct. 1, 2015

(54) Manufacturing Method of TFT Array Substrate

(71) Applicant: SHENZHEN CHINA STAR OPTOELECTRONICS TECHNOLOGY CO., LTD., Shenzhen, Guangdong (CN)

(72) Inventor: Xiangyang Xu, Shenzhen (CN)

(73) Assignee: SHENZHEN CHINA STAR OPTOELECTRONICS TECHNOLOGY CO., LTD., Shenzhen, Guangdong (CN)

(21) Appl. No.: 14/374,265

(22) PCT Filed: Apr. 17, 2014
(86) PCT No.: PCT/CN2014/075577

§ 371 Date: Jul. 24, 2014

(30) Foreign Application Priority Data
Mar. 28, 2014 (CN) 201410121731.1

(51) Int. Cl. H01L 27/12; H01L 29/66; H01L 21/311

(52) U.S. Cl. CPC H01L 27/1288; H01L 27/1218; H01L 27/124; H01L 21/311; H01L 29/66765

(57) ABSTRACT

The embodiments of the present invention disclose a manufacturing method of a TFT array substrate, which comprises the following steps: using a first photomask technology on a glass substrate to form a gate metal layer and a pixel electrode pattern, the first photomask technology is a halftone photomask technology; using a second photomask technology to form a gate insulating layer and a semiconductor layer pattern, the second photomask technology is a halftone photomask technology or a gray tone photomask technology; using a third photomask technology to form a source/drain metal layer and a channel. Achieving the embodiments of the present invention, it simplifies the process of manufacturing the a-Si semiconductor or the oxide semiconductor TFT array substrate of the tablet display panel, reducing the amount of the diaphragm plate, decreasing the producing costs.

This application submitted to Chinese Patent Office on Mar. 28, 2014, application NO. is 201410121731.1, the title of the invention is China patent priority of “manufacturing method of TFT array substrate”, the entire contents of the patent are incorporated by reference in the present application.

### BACKGROUND OF THE INVENTION

1. Field of the Invention

The present invention relates to the tablet display manufacturing technology and in particular to a manufacturing method of a thin film transistor, TFT, array substrate.

2. The Related Arts

In recent years, the display technology has been rapidly developed, the tablet display has replaced the bulky CRT monitor and deepening people's daily lives. Currently, the common tablet display comprises liquid crystal display, LCD, and organic light-emitting diode, OLED, display. The tablet display has advantages such as small size, low power consumption, no radiation, etc, which occupies dominant position in the current tablet display market.

In the array substrate of the tablet display, each pixel is equipped with a switching unit used for controlling the pixel, which is thin film transistor, TFT, TFT comprises at least a gate, a source, a drain, a gate insulating layer and an active layer. It can independently control each pixel through driving circuit; simultaneously, it won't other pixels to cause crosstalk.

Currently, the common TFT backboard mainly uses a-Si, low temperature polysilicon, metal oxide and organic semiconductor material. Technically, a-Si semiconductor technology is most simple, the technology is more mature, which is the current mainstream semiconductor material; however, the manufacturing technology using a-Si semiconductor usually needs five or four photomask technologies; the manufacturing technology using metal oxide semiconductor usually utilizes the etching block structure, which generally needs six photomask technologies. In the prior art, no matter using the a-Si semiconductor technology or the metal oxide semiconductor technology, it is not only complex process, but also high costs.

### SUMMARY OF THE INVENTION

The technical problems to be solved in the embodiment of the present invention is to provide a manufacturing method of a TFT array substrate, which can reduce the amount of the diaphragm plate, thereby decreasing the producing costs.

In order to solve the above technical issues, the embodiment of the present invention provides a manufacturing method of the TFT array substrate, which comprises the following steps:

Using a first photomask technology on a glass substrate to form a gate metal layer and a pixel electrode pattern, the first photomask technology is a halftone photomask technology;

Using a second photomask technology to form a gate insulating layer and a semiconductor layer pattern, the second photomask technology is a halftone photomask technology or a gray tone photomask technology;

Using a third photomask technology to form a source/drain metal layer and a channel.

Wherein it uses a first photomask technology on the glass substrate, the steps of forming a gate metal layer and a pixel electrode pattern comprises:

Depositing a pixel electrode layer and a gate metal layer with the predetermined thickness on the glass substrate, and coated with a photoresist;

Using halftone photomask to expose and develop the photoresist;

And then carrying on the first wet etching to the gate metal layer and the pixel electrode layer, and removing part of the photoresist; and then carrying on the second wet etching to the gate metal layer and stripping the corresponded photoresist, forming the gate metal layer and pixel electrode pattern.

Wherein the steps of Depositing a pixel electrode layer and a gate metal layer with the predetermined thickness on the glass substrate specifically are:

Using the method of stripping or thermal evaporation to deposit the gate metal film of which the thickness is 1000 Å˜6000 Å on the glass substrate and deposit the ITO pixel electrode layer or IZO pixel electrode layer of which the thickness is 100 Å˜1000 Å.

Wherein the steps of using a second photomask technology to form a gate insulating layer and a semiconductor layer pattern are:

Depositing a gate insulating layer of which the predetermined thickness is 2000 Å˜5000 Å and a-Si semiconductor thin film of which the thickness is 1000 Å˜3000 Å on the glass substrate formed the gate metal layer and the pixel electrode pattern, and coating photoresist.

Using halftone photomask technology to expose and develop the photoresist;

And then carrying on the dry etching to the insulating protective layer on the channel and the first dry etching to the a-Si semiconductor thin film, removing part of the photoresist; and then carrying on the second dry etching to the a-Si semiconductor thin film, and stripping the corresponded photoresist, forming the gate insulating layer and the semiconductor layer pattern.

Wherein the steps of using a second photomask technology to form a gate insulating layer and a semiconductor layer pattern are:

Depositing a gate insulating layer of which the predetermined thickness is 2000 Å˜5000 Å and a-Si semiconductor thin film of which the thickness is 1000 Å˜3000 Å on the glass substrate formed the gate metal layer and the pixel electrode pattern, and coating photoresist.

Using halftone photomask technology to expose and develop the photoresist;

And then carrying on the first etching to the insulating protective layer on the channel and the a-Si semiconductor thin film, carrying on the etching to the gate insulating protective layer, removing part of the photoresist; carrying on the second etching to the insulating protective layer on the channel and the a-Si semiconductor thin film, removing part of the photoresist second time, carrying on the third etching to the insulating protective layer on the channel, and stripping the corresponded photoresist, forming the gate insulating layer and a-Si semiconductor layer and the channel insulating protective layer pattern.

Wherein the steps of using a second photomask technology to form a gate insulating layer and a semiconductor layer pattern are:

Depositing a gate insulating layer of which the predetermined thickness is 2000 Å˜5000 Å and a-Si semiconductor thin film of which the thickness is 1000 Å˜3000 Å on the glass substrate formed the gate metal layer and the pixel electrode pattern, and coating photoresist.

Using halftone photomask technology to expose and develop the photoresist;

And then carrying on the first dry etching to the insulating protective layer on the channel and the oxide semiconductor thin film and the etching block layer, removing part of the photoresist; and then carrying on the second etching to the insulating protective layer on the channel and the oxide semiconductor thin film, removing part of the photoresist second time, carrying on the second etching to the etching block layer, and stripping the corresponded photoresist, forming the gate insulating layer, the oxide semiconductor thin film and the etching block layer pattern.

Wherein the steps of using a third photomask technology to form a source/drain metal layer and a channel are:

Depositing a source/drain metal thin film with the predetermined thickness on the glass substrate formed a gate insulating layer and a semiconductor layer pattern, and coated with a photoresist;

Using the third photomask technology to dispose and develop, carrying on the wet etching to the source/drain metal thin film, carrying on the dry etching to the channel, and stripping the corresponded photoresist, forming the source metal layer, the drain metal layer and the channel.

Wherein the steps of using a third photomask technology to form a source/drain metal layer and a channel are:

Depositing a source/drain metal thin film with the predetermined thickness on the glass substrate formed a gate insulating layer and a semiconductor layer pattern, and coated with a photoresist;

Using the third photomask technology to dispose and develop, carrying on the wet etching to the source/drain metal thin film, carrying on the dry etching to the channel, and stripping the corresponded photoresist, forming the source metal layer, the drain metal layer and the channel.

Wherein the steps of depositing a source/drain metal thin film with the predetermined thickness on the glass substrate formed a gate insulating layer and a semiconductor layer pattern specifically are:

Using the method of stripping or thermal evaporation to deposit the source/drain metal thin film of which the thickness is 1000 Å˜6000 Å.

Wherein the depositing gate insulating layer, the semiconductor thin film, the oxide semiconductor thin film or the etching block layer use plasma enhanced chemical vapor deposition method, the gate insulating layer uses SiNx, the oxide semiconductor thin film uses one kind of ZnO, InZnO, ZnSnO, GaInZnO or ZrInZnO.

Correspondingly, the embodiment of the present invention also provides a manufacturing method of the TFT array substrate, which comprises the following steps:

Using a first photomask technology on a glass substrate to form a gate metal layer and a pixel electrode pattern, the first photomask technology is a halftone photomask technology;

Using a second photomask technology to form a gate insulating layer and a semiconductor layer pattern, the second photomask technology is a halftone photomask technology or a gray tone photomask technology;

Using a third photomask technology to form a source/drain metal layer and a channel.

Wherein it uses a first photomask technology on the glass substrate, the steps of forming a gate metal layer and a pixel electrode pattern comprises:

Depositing a pixel electrode layer and a gate metal layer with the predetermined thickness on the glass substrate, and coated with a photoresist;

Using halftone photomask to expose and develop the photoresist;

And then carrying on the first wet etching to the gate metal layer and the pixel electrode layer, and removing part of the photoresist; and then carrying on the second wet etching to the gate metal layer and stripping the corresponded photoresist, forming the gate metal layer and pixel electrode pattern.

Wherein the steps of Depositing a pixel electrode layer and a gate metal layer with the predetermined thickness on the glass substrate specifically are:

Using the method of stripping or thermal evaporation to deposit the gate metal film of which the thickness is 1000 Å˜6000 Å on the glass substrate and deposit the ITO pixel electrode layer or IZO pixel electrode layer of which the thickness is 100 Å˜1000 Å.

Wherein the steps of using a second photomask technology to form a gate insulating layer and a semiconductor layer pattern are:

Depositing a gate insulating layer of which the predetermined thickness is 2000 Å˜5000 Å and a-Si semiconductor thin film of which the thickness is 1000 Å˜3000 Å on the glass substrate formed the gate metal layer and the pixel electrode pattern, and coating photoresist.

Using halftone photomask technology to expose and develop the photoresist;

And then carrying on the dry etching to the insulating protective layer on the channel and the first dry etching to the a-Si semiconductor thin film, removing part of the photoresist; and then carrying on the second dry etching to the a-Si semiconductor thin film, and stripping the corresponded photoresist, forming the gate insulating layer and the semiconductor layer pattern.

Wherein the steps of using a second photomask technology to form a gate insulating layer and a semiconductor layer pattern are:

Depositing a gate insulating layer of which the predetermined thickness is 2000 Å˜5000 Å and a-Si semiconductor thin film of which the thickness is 1000 Å˜3000 Å on the glass substrate formed the gate metal layer and the pixel electrode pattern, and coating photoresist.

Using halftone photomask technology to expose and develop the photoresist;

And then carrying on the first etching to the insulating protective layer on the channel and the a-Si semiconductor thin film, carrying on the etching to the gate insulating protective layer, removing part of the photoresist; carrying on the second etching to the insulating protective layer on the channel and the a-Si semiconductor thin film, removing part of the photoresist second time, carrying on the third etching to the insulating protective layer on the channel, and stripping the corresponded photoresist, forming the gate insulating layer and a-Si semiconductor layer and the channel insulating protective layer pattern.

Wherein the steps of using a second photomask technology to form a gate insulating layer and a semiconductor layer pattern are:

Depositing a gate insulating layer of which the predetermined thickness is 2000 Å˜5000 Å and a-Si semiconductor thin film of which the thickness is 1000 Å˜3000 Å on the glass substrate formed the gate metal layer and the pixel electrode pattern, and coating photoresist.

Using halftone photomask technology to expose and develop the photoresist;

And then carrying on the first dry etching to the insulating protective layer on the channel and the oxide semiconductor thin film and the etching block layer, removing part of the photoresist; and then carrying on the second etching to the insulating protective layer on the channel and the oxide semiconductor thin film, removing part of the photoresist second time, carrying on the second etching to the etching block layer, and stripping the corresponded photoresist, forming the gate insulating layer, the oxide semiconductor thin film and the etching block layer pattern.

Wherein the steps of using a third photomask technology to form a source/drain metal layer and a channel are:

Depositing a source/drain metal thin film with the predetermined thickness on the glass substrate formed a gate insulating layer and a semiconductor layer pattern, and coated with a photoresist;

Using the third photomask technology to dispose and develop, carrying on the wet etching to the source/drain metal thin film, carrying on the dry etching to the channel, and stripping the corresponded photoresist, forming the source metal layer, the drain metal layer and the channel.

Wherein the steps of depositing a source/drain metal thin film with the predetermined thickness on the glass substrate formed a gate insulating layer and a semiconductor layer pattern specifically are:

Using the method of stripping or thermal evaporation to deposit the source/drain metal thin film of which the thickness is 1000 Å˜6000 Å.

Achieving the embodiments of the present invention has the following benefits:

Achieving the embodiments of the present invention, when using the a-Si silicon semiconductor or the metal oxide semiconductor manufacturing technology, it only needs three photomask technologies, which simplifies the process of manufacturing the TFT array substrate of the tablet display panel, reducing the amount of the diaphragm plate, decreasing the producing costs.

### BRIEF DESCRIPTION OF THE DRAWINGS

In order to more clearly illustrate the embodiments of the present invention of the technical solution of the prior art, the following will briefly describe the drawings of the embodiments or the prior art; apparently, the drawings described as below are just several embodiments of the present invention, for the ordinary technical personnel in the art, under the premise of no creative labor, the other drawings also can be obtained according to these drawings.

FIG. 1 is a flow diagram of a manufacturing method of TFT array substrate in an embodiment provided by the present invention;

FIG. 2 is a structure diagram of an array substrate after forming a gate metal layer and a pixel electrode layer by using the first photomask in FIG. 1;

FIG. 3 is a structure diagram of an array substrate after forming a gate insulating protective layer and a-Si semiconductor layer by using the second photomask in FIG. 1;

FIG. 4 is a structure diagram of an array substrate after forming a source/drain metal layer by using the third photomask in FIG. 1;

FIG. 5 is a structure diagram of a formed TFT array substrate in FIG. 1;

FIG. 6 is a structure diagram of an array substrate after forming a gate metal layer and a pixel electrode layer by using the first photomask in the other embodiment of a manufacturing method of TFT array substrate provided by the present invention;

FIG. 7 is a structure diagram of an array substrate after forming a gate insulating protective layer and a semiconductor layer by using the second photomask in the other embodiment of a manufacturing method of TFT array substrate provided by the present invention;

FIG. 8 is a structure diagram of a formed array substrate after FIG. 7 finishing;

FIG. 9 is a structure diagram of an array substrate after forming a source/drain metal layer by using the third photomask.

### DETAILED DESCRIPTION OF THE PREFERRED EMBODIMENTS

The following reference drawings describe the preferred embodiments of the present invention.

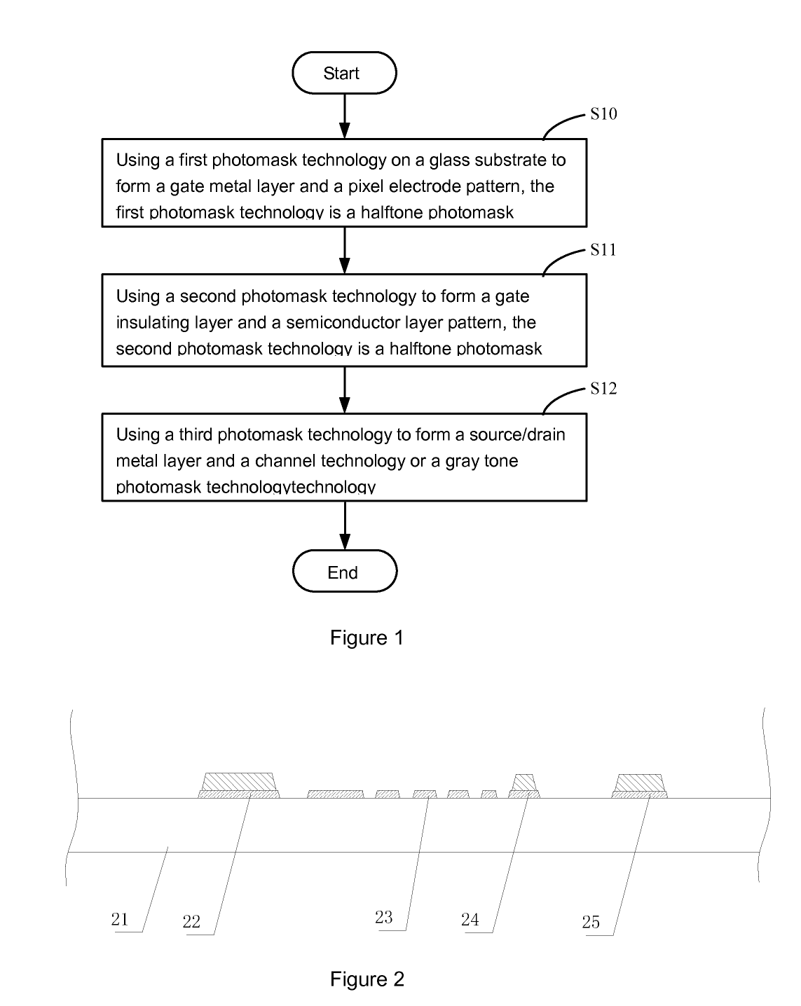

As shown in FIG. 1, which is a flow diagram of a manufacturing method of TFT array substrate in an embodiment provided by the present invention; in the embodiment, the method is suitable for manufacturing an a-Si array substrate of the tablet panel, which comprises the following steps:

Step S10, using a first photomask technology on a glass substrate to form a gate metal layer and a pixel electrode pattern, the first photomask technology is a halftone photomask technology;

Specifically, step comprises:

Depositing a pixel electrode layer and a gate metal layer with the predetermined thickness on the glass substrate, and coated with a photoresist, for example, in an embodiment, using the method of stripping or thermal evaporation to deposit the gate metal film of which the thickness is 1000 Å˜6000 Å on the glass substrate and deposit the ITO pixel electrode layer or IZO pixel electrode layer of which the thickness is 100 Å˜1000 Å, wherein the gate metal thin film could be used as Cr, Mo, Al, Cu, etc.

Using halftone photomask to expose and develop the photoresist;

And then carrying on the first wet etching to the gate metal layer and the pixel electrode layer, and removing part of the photoresist; and then carrying on the second wet etching to the gate metal layer and stripping the corresponded photoresist, forming the gate metal layer, pixel electrode pattern and com pattern, wherein the gate metal layer pattern comprises a gate and a gate pad.

Wherein the structure diagram of an array substrate after forming a gate metal layer and a pixel electrode layer is shown in FIG. 2. Specifically, it comprises a glass substrate 21, a gate 22 formed on the glass substrate, a pixel electrode 23, a com 24 and a gate pad 25.

Step S11, using a second photomask technology to form a gate insulating layer and a semiconductor layer pattern, the second photomask technology is a halftone photomask technology;

Specifically, the steps comprises:

Depositing a gate insulating layer (such as SiNx) and a-Si semiconductor thin film with the predetermined thickness on the glass substrate formed the gate metal layer and the pixel electrode pattern, and coating photoresist, for example, in an embodiment, using a chemical vapor deposition, depositing a gate insulating layer of which the predetermined thickness is 2000 Å˜5000 Å and a-Si semiconductor thin film of which the thickness is 1000 Å˜3000 Å on the glass substrate formed the gate metal layer and the pixel electrode pattern; specifically, it can be achieved the depositing process by plasma enhanced chemical vapor deposition, PECVD;

Using halftone photomask technology to expose and develop the photoresist, forming a certain pattern;

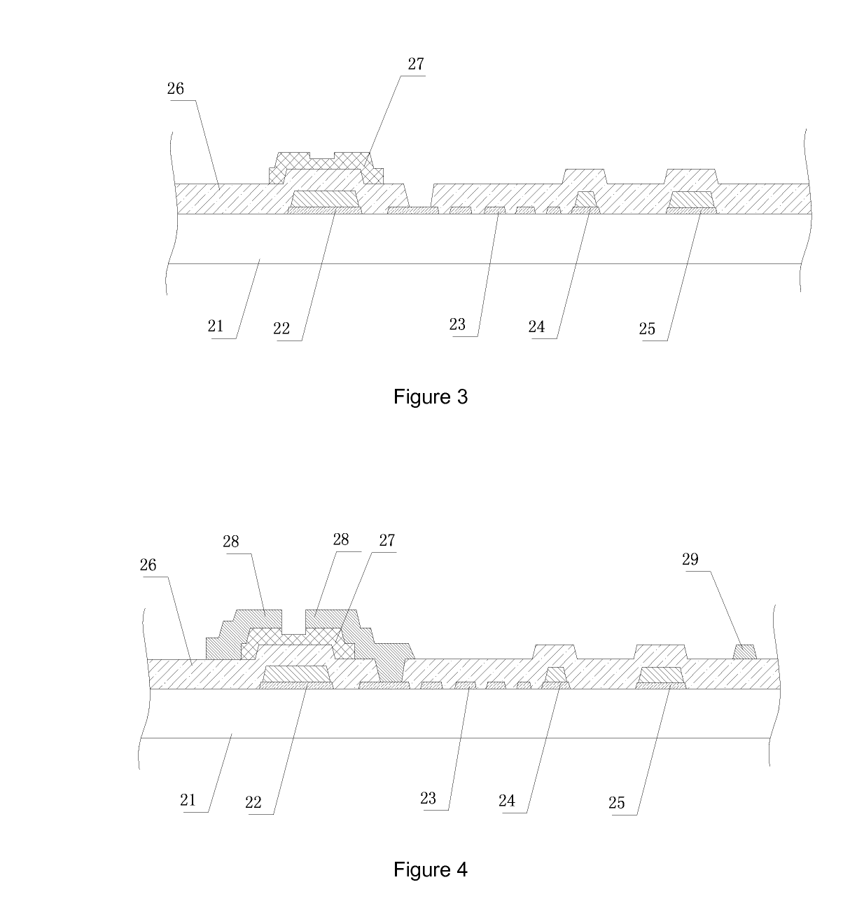

And then carrying on the dry etching to the insulating protective layer on the channel and the first dry etching to the a-Si semiconductor thin film, removing part of the photoresist; and then carrying on the second dry etching to the a-Si semiconductor thin film, and stripping the corresponded photoresist, forming the gate insulating layer and the semiconductor layer pattern.

Wherein, the structure diagram of an array substrate after forming a gate insulating protective layer and a-Si semiconductor layer is shown in FIG. 3. Wherein, the mark 26 represents the gate insulating layer, the mark 76 represents a-Si semiconductor thin film, the component which the other marks correspond to can be referred by the introduction in FIG. 2.

S12, using a third photomask technology to form a source/drain metal layer and a channel, wherein the third photomask technology can be an ordinary photomask technology;

Depositing a source/drain metal thin film with the predetermined thickness on the glass substrate formed a gate insulating layer and a semiconductor layer pattern, and coated with a photoresist, for example, in an embodiment, using the method of stripping or thermal evaporation to deposit the source/drain metal thin film of which the thickness is 1000 Å˜6000 Å;

Using the third photomask technology to dispose and develop, carrying on the wet etching to the source/drain metal thin film, carrying on the dry etching to the channel, and stripping the corresponded photoresist, forming the source metal layer, the drain metal layer, the channel and the data pad.

Wherein the structure diagram of an array substrate after forming a source/drain metal layer is shown in FIG. 4. Wherein the mark 28 represents the source/drain metal layer, the mark 29 represents the data pad, the component which the other marks correspond to can be referred by the introduction in FIG. 3.

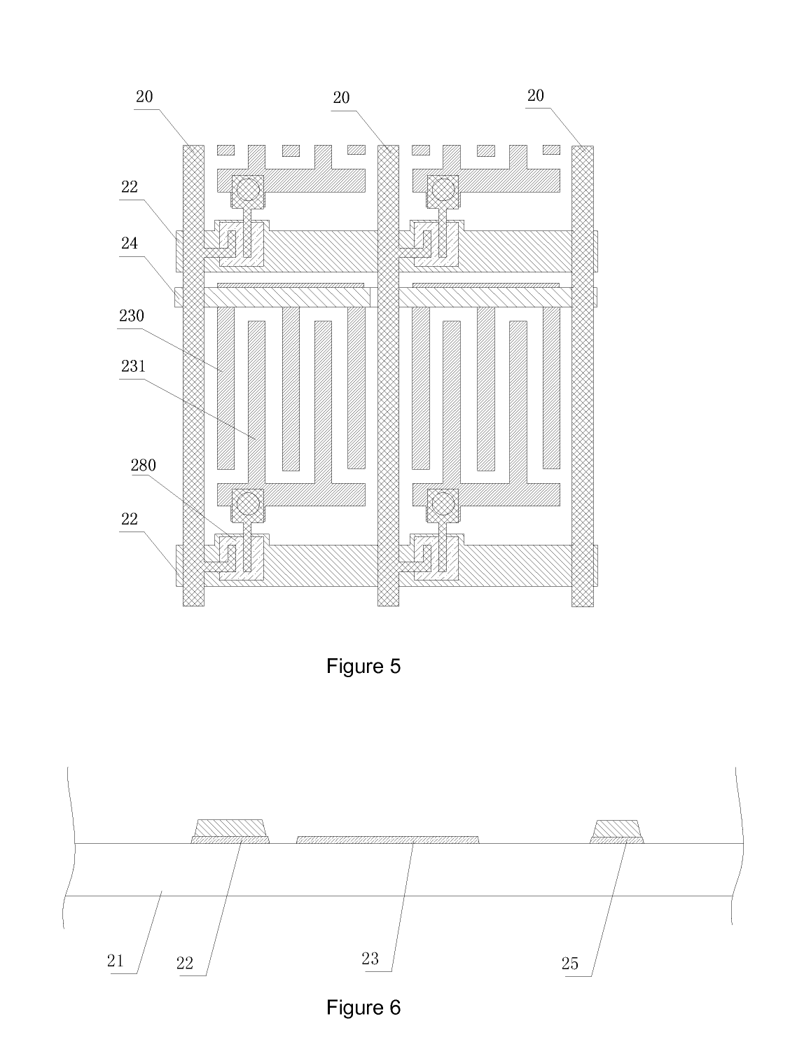

As shown in FIG. 5, which is a structure diagram of a formed TFT array substrate according to the method in FIG. 1, the mark 280 represents a TFT unit, which comprises the source/drain metal layer and the channel described above. The mark 20 represents the data line, the component which the other marks correspond to can be referred by the introduction in FIG. 4.

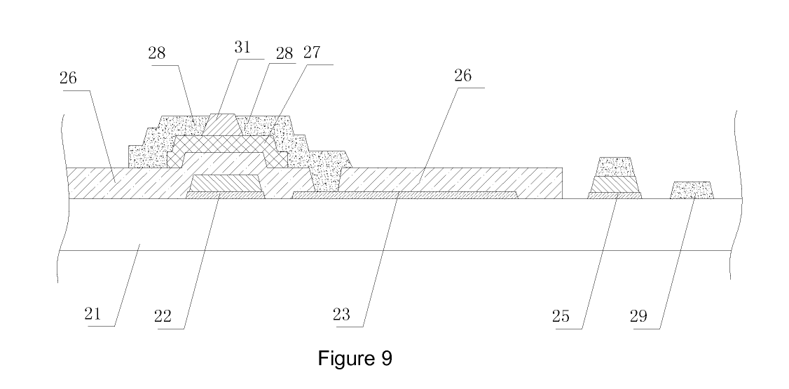

Correspondingly, in the other embodiments, the method provided by the present invention can also be used for manufacturing process of the TFT array substrate of the metal oxide semiconductor technology. As shown in FIG. 6 to FIG. 9, which illustrate the steps of using the TFT array substrate of the metal oxide semiconductor technology. Specifically, the embodiment comprises the following steps:

First step, using a first photomask technology on a glass substrate to form a gate metal layer and a pixel electrode pattern, the first photomask technology is a halftone photomask technology;

Specifically, step comprises:

Depositing a pixel electrode layer and a gate metal layer with the predetermined thickness on the glass substrate, and coated with a photoresist, for example, in an embodiment, using the method of stripping or thermal evaporation to deposit the gate metal film of which the thickness is 1000 Å˜6000 Å on the glass substrate and deposit the ITO pixel electrode layer or IZO pixel electrode layer of which the thickness is 100 Å˜1000 Å, wherein the gate metal thin film could be used as Cr, Mo, Al, Cu, etc.

Using halftone photomask to expose and develop the photoresist;

And then carrying on the first wet etching to the gate metal layer and the pixel electrode layer, and removing part of the photoresist; and then carrying on the second wet etching to the gate metal layer and stripping the corresponded photoresist, forming the gate metal layer, pixel electrode pattern and corn pattern, wherein the gate metal layer pattern comprises a gate and a gate pad.

Wherein the structure diagram of an array substrate after forming a gate metal layer and a pixel electrode layer is shown in FIG. 6. Specifically, it comprises a glass substrate 21, a gate 22 formed on the glass substrate, a pixel electrode 23, a corn 24 and a gate pad 25.

Second step, using a second photomask technology to form a gate insulating layer and a semiconductor layer pattern, the second photomask technology is a halftone photomask technology;

Specifically, the steps comprises:

Depositing a gate insulating layer (such as SiNx) and a-Si semiconductor thin film with the predetermined thickness on the glass substrate formed the gate metal layer and the pixel electrode pattern, and coating photoresist, for example, in an embodiment, using a chemical vapor deposition, depositing a gate insulating layer of which the predetermined thickness is 2000 Å˜5000 Å and a-Si semiconductor thin film of which the thickness is 1000 Å˜3000 Å on the glass substrate formed the gate metal layer and the pixel electrode pattern; specifically, it can be achieved the depositing process by plasma enhanced chemical vapor deposition, PECVD, wherein the oxide semiconductor thin film could be ZnO, InZnO, ZnSnO, GaInZnO or ZrInZnO, etc, such metal oxide semiconductor thin film;

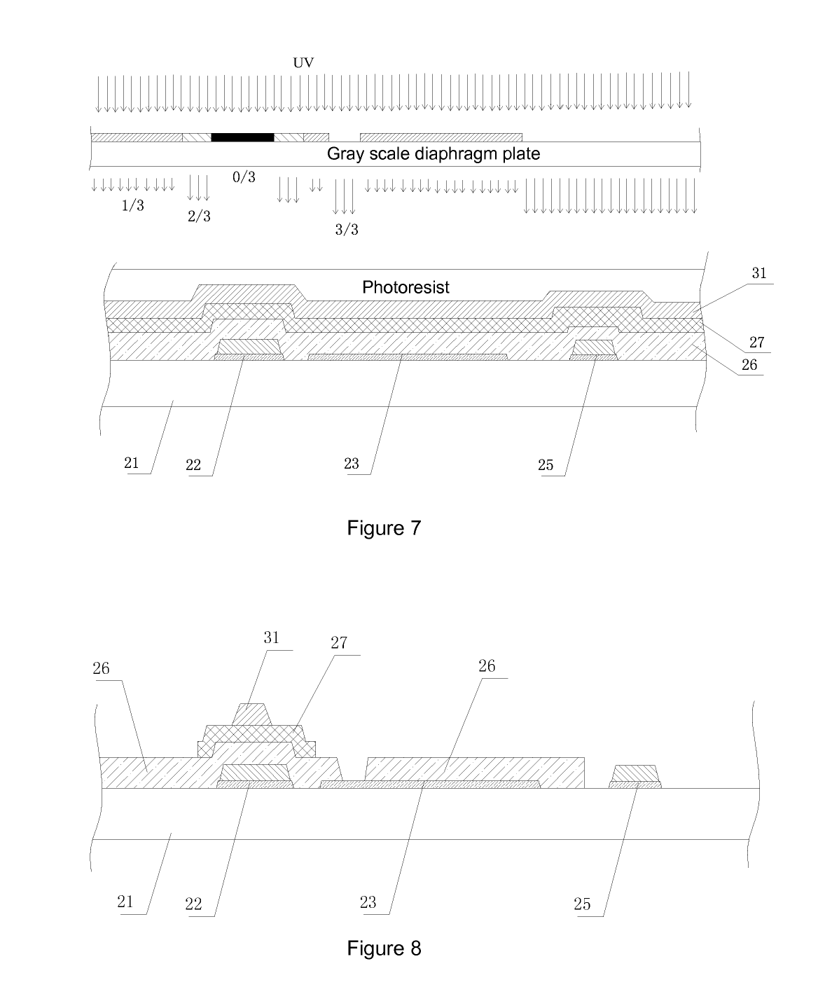

Using halftone photomask technology to expose and develop the photoresist, specifically using a gray scale diaphragm plate with a variety of light transmittance, as shown in FIG. 7, which shows such gray scale diaphragm plate, in the gray scale diaphragm plate, each different region has the different light transmittance. FIG. 7 shows four regions, the light transmittance of which is respectively 0/3, 1/3, 2/3 and 3/3;

And then carrying on the first dry etching to the insulating protective layer on the channel and the oxide semiconductor thin film and the etching block layer, removing part of the photoresist; and then carrying on the second etching to the insulating protective layer on the channel and the oxide semiconductor thin film, removing part of the photoresist second time, carrying on the second etching to the etching block layer, and stripping the corresponded photoresist, forming the gate insulating layer, the oxide semiconductor thin film and the etching block layer pattern.

Wherein the structure diagram of the array substrate after forming the gate insulating layer and the oxide semiconductor layer pattern is shown in FIG. 8. Wherein the mark 26 represents the gate insulating layer, the mark 76 represents the oxide semiconductor layer thin film, the mark 31 represents the etching block layer; the component which the other marks correspond to can be referred by the introduction in FIG. 6.

Third step, using a third photomask technology to form a source/drain metal layer and a channel, wherein the third photomask technology could be an ordinary photomask technology;

Depositing a source/drain metal thin film with the predetermined thickness on the glass substrate formed a gate insulating layer and a semiconductor layer pattern, and coated with a photoresist, for example, in an embodiment, using the method of stripping or thermal evaporation to deposit the source/drain metal thin film of which the thickness is 1000 Å˜6000 Å;

Using the third photomask technology to dispose and develop, carrying on the wet etching to the source/drain metal thin film, carrying on the dry etching to the channel, and stripping the corresponded photoresist, forming the source metal layer, the drain metal layer, the channel and the data pad.

Wherein the structure diagram of an array substrate after forming a source/drain metal layer is shown in FIG. 4. Wherein the mark 28 represents the source/drain metal layer, the mark 29 represents the data pad, the component which the other marks correspond to can be referred by the introduction in FIG. 8.

It can be realized that, in the other embodiments, it also can use a gray tone photomask technology when manufacturing the a-Si array substrate of tablet, the method of which is similar to what FIG. 1 shows, it only needs to alternate the second photomask technology to the gray tone photomask technology, thus in this embodiment, the steps of using a second photomask technology to form a gate insulating layer and a semiconductor layer pattern in step S11 specifically comprises:

Depositing a gate insulating layer of which the predetermined thickness is 2000 Å˜5000 Å and a-Si semiconductor thin film of which the thickness is 1000 Å˜3000 Å on the glass substrate formed the gate metal layer and the pixel electrode pattern, and coating photoresist.

Using halftone photomask technology to expose and develop the photoresist, the theory of the gray tone photomask technology can be referred by the introduction of FIG. 7;

And then carrying on the first etching to the insulating protective layer on the channel and the semiconductor layer, carrying on the etching to the gate insulating protective layer, removing part of the photoresist; carrying on the second etching to the insulating protective layer on the channel and the semiconductor layer, removing part of the photoresist second time, carrying on the third etching to the insulating protective layer on the channel, and stripping the corresponded photoresist, forming the gate insulating layer and the semiconductor layer and the channel insulating protective layer pattern.

However, step 10 and step 12 are the same as FIG. 1, please refer to the above description, there is no more description.

Achieving the embodiments of the present invention has the following benefits:

Achieving the embodiments of the present invention, when using the a-Si silicon semiconductor or the metal oxide semiconductor manufacturing technology, it only needs three photomask technologies, which simplifies the process of manufacturing the TFT array substrate of the tablet display panel, reducing the amount of the diaphragm plate, decreasing the producing costs.

The preferred embodiments according to the present invention are mentioned above, which cannot be used to define the scope of the right of the present invention. Those variations of equivalent structure or equivalent process according to the present specification and the drawings or directly or indirectly applied in other areas of technology are considered encompassed in the scope of protection defined by the claims of the present invention.

What is claimed is:

1. A manufacturing method of a TFT array substrate, wherein which comprises following steps:
Using a first photomask technology on a glass substrate to form a gate metal layer and a pixel electrode pattern, the first photomask technology is a halftone photomask technology;
Using a second photomask technology to form a gate insulating layer and a semiconductor layer pattern, the second photomask technology is a halftone photomask technology or a gray tone photomask technology;
Using a third photomask technology to form a source/drain metal layer and a channel.

2. The manufacturing method of a TFT array substrate as claimed in claim 1, wherein it uses a first photomask technology on the glass substrate, the steps of forming a gate metal layer and a pixel electrode pattern comprises:
Depositing a pixel electrode layer and a gate metal layer with the predetermined thickness on the glass substrate, and coated with a photoresist;
Using halftone photomask to expose and develop the photoresist;
And then carrying on the first wet etching to the gate metal layer and the pixel electrode layer, and removing part of the photoresist; and then carrying on the second wet etching to the gate metal layer and stripping the corresponded photoresist, forming the gate metal layer and pixel electrode pattern.

3. The manufacturing method of a TFT array substrate as claimed in claim 2, wherein the steps of Depositing a pixel electrode layer and a gate metal layer with the predetermined thickness on the glass substrate specifically are:
Using the method of stripping or thermal evaporation to deposit the gate metal film of which the thickness is 1000 Å˜6000 Å on the glass substrate and deposit the ITO pixel electrode layer or IZO pixel electrode layer of which the thickness is 100 Å˜1000 Å.

4. The manufacturing method of a TFT array substrate as claimed in claim 3, wherein the steps of using a second photomask technology to form a gate insulating layer and a semiconductor layer pattern are:
Depositing a gate insulating layer of which the predetermined thickness is 2000 Å˜5000 Å and a-Si semiconductor thin film of which the thickness is 1000 Å˜3000 Å on the glass substrate formed the gate metal layer and the pixel electrode pattern, and coating photoresist.
Using halftone photomask technology to expose and develop the photoresist;
And then carrying on the dry etching to the insulating protective layer on the channel and the first dry etching to the a-Si semiconductor thin film, removing part of the photoresist; and then carrying on the second dry etching to the a-Si semiconductor thin film, and stripping the corresponded photoresist, forming the gate insulating layer and the semiconductor layer pattern.

5. The manufacturing method of a TFT array substrate as claimed in claim 3, wherein the steps of using a second photomask technology to form a gate insulating layer and a semiconductor layer pattern are:
Depositing a gate insulating layer of which the predetermined thickness is 2000 Å˜5000 Å and a-Si semiconductor thin film of which the thickness is 1000 Å˜3000 Å on the glass substrate formed the gate metal layer and the pixel electrode pattern, and coating photoresist.
Using halftone photomask technology to expose and develop the photoresist;
And then carrying on the first etching to the insulating protective layer on the channel and the a-Si semiconductor thin film, carrying on the etching to the gate insulating protective layer, removing part of the photoresist; carrying on the second etching to the insulating protective layer on the channel and the a-Si semiconductor thin film, removing part of the photoresist second time, carrying on the third etching to the insulating protective layer on the channel, and stripping the corresponded photoresist, forming the gate insulating layer and a-Si semiconductor layer and the channel insulating protective layer pattern.

6. The manufacturing method of a TFT array substrate as claimed in claim 3, wherein the steps of using a second photomask technology to form a gate insulating layer and a semiconductor layer pattern are:
Depositing a gate insulating layer of which the predetermined thickness is 2000 Å˜5000 Å and a-Si semiconductor thin film of which the thickness is 1000 Å˜3000 Å on the glass substrate formed the gate metal layer and the pixel electrode pattern, and coating photoresist.
Using halftone photomask technology to expose and develop the photoresist;
And then carrying on the first dry etching to the insulating protective layer on the channel and the oxide semiconductor thin film and the etching block layer, removing part of the photoresist; and then carrying on the second etching to the insulating protective layer on the channel and the oxide semiconductor thin film, removing part of the photoresist second time, carrying on the second etching to the etching block layer, and stripping the corresponded photoresist, forming the gate insulating layer, the oxide semiconductor thin film and the etching block layer pattern.

7. The manufacturing method of a TFT array substrate as claimed in claim 4, wherein the steps of using a third photomask technology to form a source/drain metal layer and a channel are:
Depositing a source/drain metal thin film with the predetermined thickness on the glass substrate formed a gate insulating layer and a semiconductor layer pattern, and coated with a photoresist;
Using the third photomask technology to dispose and develop, carrying on the wet etching to the source/drain metal thin film, carrying on the dry etching to the channel, and stripping the corresponded photoresist, forming the source metal layer, the drain metal layer and the channel.

8. The manufacturing method of a TFT array substrate as claimed in claim 5, wherein the steps of using a third photomask technology to form a source/drain metal layer and a channel are:
Depositing a source/drain metal thin film with the predetermined thickness on the glass substrate formed a gate insulating layer and a semiconductor layer pattern, and coated with a photoresist;
Using the third photomask technology to dispose and develop, carrying on the wet etching to the source/drain metal thin film, carrying on the dry etching to the channel, and stripping the corresponded photoresist, forming the source metal layer, the drain metal layer and the channel.

9. The manufacturing method of a TFT array substrate as claimed in claim 6, wherein the steps of using a third photomask technology to form a source/drain metal layer and a channel are:
Depositing a source/drain metal thin film with the predetermined thickness on the glass substrate formed a gate insulating layer and a semiconductor layer pattern, and coated with a photoresist;
Using the third photomask technology to dispose and develop, carrying on the wet etching to the source/drain metal thin film, carrying on the dry etching to the channel, and stripping the corresponded photoresist, forming the source metal layer, the drain metal layer and the channel.

10. The manufacturing method of a TFT array substrate as claimed in claim 7, wherein the steps of depositing a source/drain metal thin film with the predetermined thickness on the glass substrate formed a gate insulating layer and a semiconductor layer pattern specifically are:
Using the method of stripping or thermal evaporation to deposit the source/drain metal thin film of which the thickness is 1000 Å˜6000 Å.

11. The manufacturing method of a TFT array substrate as claimed in claim 10, wherein the depositing gate insulating layer, the semiconductor thin film, the oxide semiconductor thin film or the etching block layer use plasma enhanced chemical vapor deposition method, the gate insulating layer uses SiNx, the oxide semiconductor thin film uses one kind of ZnO, InZnO, ZnSnO, GaInZnO or ZrInZnO.

12. A manufacturing method of a TFT array substrate, wherein which comprises following steps:
Using a first photomask technology on a glass substrate to form a gate metal layer and a pixel electrode pattern, the first photomask technology is a halftone photomask technology;
Using a second photomask technology to form a gate insulating layer and a semiconductor layer pattern, the second photomask technology is a halftone photomask technology or a gray tone photomask technology;
Using a third photomask technology to form a source/drain metal layer and a channel.
Wherein it uses a first photomask technology on the glass substrate, the steps of forming a gate metal layer and a pixel electrode pattern comprises:
Depositing a pixel electrode layer and a gate metal layer with the predetermined thickness on the glass substrate, and coated with a photoresist;
Using halftone photomask to expose and develop the photoresist;
And then carrying on the first wet etching to the gate metal layer and the pixel electrode layer, and removing part of the photoresist; and then carrying on the second wet etching to the gate metal layer and stripping the corresponded photoresist, forming the gate metal layer and pixel electrode pattern.

13. The manufacturing method of a TFT array substrate as claimed in claim 12, wherein the steps of Depositing a pixel electrode layer and a gate metal layer with the predetermined thickness on the glass substrate specifically are:
Using the method of stripping or thermal evaporation to deposit the gate metal film of which the thickness is 1000 Å˜6000 Å on the glass substrate and deposit the ITO pixel electrode layer or IZO pixel electrode layer of which the thickness is 100 Å˜1000 Å.

14. The manufacturing method of a TFT array substrate as claimed in claim 13, wherein the steps of using a second photomask technology to form a gate insulating layer and a semiconductor layer pattern are:
Depositing a gate insulating layer of which the predetermined thickness is 2000 Å˜5000 Å and a-Si semiconductor thin film of which the thickness is 1000 Å˜3000 Å on the glass substrate formed the gate metal layer and the pixel electrode pattern, and coating photoresist.
Using halftone photomask technology to expose and develop the photoresist;
And then carrying on the dry etching to the insulating protective layer on the channel and the first dry etching to the a-Si semiconductor thin film, removing part of the photoresist; and then carrying on the second dry etching to the a-Si semiconductor thin film, and stripping the corresponded photoresist, forming the gate insulating layer and the semiconductor layer pattern.

15. The manufacturing method of a TFT array substrate as claimed in claim 13, wherein the steps of using a second photomask technology to form a gate insulating layer and a semiconductor layer pattern are:
Depositing a gate insulating layer of which the predetermined thickness is 2000 Å˜5000 Å and a-Si semiconductor thin film of which the thickness is 1000 Å˜3000 Å on the glass substrate formed the gate metal layer and the pixel electrode pattern, and coating photoresist.
Using halftone photomask technology to expose and develop the photoresist;
And then carrying on the first etching to the insulating protective layer on the channel and the a-Si semiconductor thin film, carrying on the etching to the gate insulating protective layer, removing part of the photoresist; carrying on the second etching to the insulating protective layer on the channel and the a-Si semiconductor thin film, removing part of the photoresist second time, carrying on the third etching to the insulating protective layer on the channel, and stripping the corresponded photoresist, forming the gate insulating layer and a-Si semiconductor layer and the channel insulating protective layer pattern.

16. The manufacturing method of a TFT array substrate as claimed in claim 13, wherein the steps of using a second photomask technology to form a gate insulating layer and a semiconductor layer pattern are:
Depositing a gate insulating layer of which the predetermined thickness is 2000 Å˜5000 Å and a-Si semiconductor thin film of which the thickness is 1000 Å˜3000 Å on the glass substrate formed the gate metal layer and the pixel electrode pattern, and coating photoresist.
Using halftone photomask technology to expose and develop the photoresist;
And then carrying on the first dry etching to the insulating protective layer on the channel and the oxide semiconductor thin film and the etching block layer, removing part of the photoresist; and then carrying on the second etching to the insulating protective layer on the channel and the oxide semiconductor thin film, removing part of the photoresist second time, carrying on the second etching to the etching block layer, and stripping the corresponded photoresist, forming the gate insulating layer, the oxide semiconductor thin film and the etching block layer pattern.

17. The manufacturing method of a TFT array substrate as claimed in claim 14, wherein the steps of using a third photomask technology to form a source/drain metal layer and a channel are:
Depositing a source/drain metal thin film with the predetermined thickness on the glass substrate formed a gate insulating layer and a semiconductor layer pattern, and coated with a photoresist;
Using the third photomask technology to dispose and develop, carrying on the wet etching to the source/drain metal thin film, carrying on the dry etching to the channel, and stripping the corresponded photoresist, forming the source metal layer, the drain metal layer and the channel.

18. The manufacturing method of a TFT array substrate as claimed in claim 15, wherein the steps of using a third photomask technology to form a source/drain metal layer and a channel are:
Depositing a source/drain metal thin film with the predetermined thickness on the glass substrate formed a gate insulating layer and a semiconductor layer pattern, and coated with a photoresist;
Using the third photomask technology to dispose and develop, carrying on the wet etching to the source/drain metal thin film, carrying on the dry etching to the channel, and stripping the corresponded photoresist, forming the source metal layer, the drain metal layer and the channel.

19. The manufacturing method of a TFT array substrate as claimed in claim 16, wherein the steps of using a third photomask technology to form a source/drain metal layer and a channel are:
Depositing a source/drain metal thin film with the predetermined thickness on the glass substrate formed a gate insulating layer and a semiconductor layer pattern, and coated with a photoresist;
Using the third photomask technology to dispose and develop, carrying on the wet etching to the source/drain metal thin film, carrying on the dry etching to the channel, and stripping the corresponded photoresist, forming the source metal layer, the drain metal layer and the channel.

20. The manufacturing method of a TFT array substrate as claimed in claim 18, wherein the steps of depositing a source/drain metal thin film with the predetermined thickness on the glass substrate formed a gate insulating layer and a semiconductor layer pattern specifically are:
Using the method of stripping or thermal evaporation to deposit the source/drain metal thin film of which the thickness is 1000 Å˜6000 Å.
